(19) United States
(12) Patent Application Publication
(10) Pub. No.: US 2015/0270184 A1
(43) Pub. Date: Sep. 24, 2015

(54) Location-Shifted Probe Pads For Pre-Bond Testing

(71) Applicant: Avago Technologies General IP (Singapore) Pte. Ltd., Singapore (SG)

(72) Inventor: Elaine Robbins Kleinfeld, Macungie, PA (US)

(73) Assignee: Avago Technologies General IP (Singapore) Pte. Ltd., Singapore (SG)

(21) Appl. No.: 14/219,282

(22) Filed: Mar. 19, 2014

(51) Int. Cl. H01L 21/66; G01R 31/26; G01R 1/06

(52) U.S. Cl. CPC H01L 22/30; G01R 1/06; G01R 31/2644

(57) ABSTRACT

An arrangement for performing pre-bond testing of a wafer of semiconductor devices utilizes probe pads that are location-shifted into wafer regions adjacent to the devices such that when the pre-bond testing is completed and the wafer is separated into individual elements, the electrical connection between the pre-bond probe pad and tested device is broken. The adjacent wafer regions may be “vacant” areas or another device region. When separated into individual components, a given pre-bond probe pad and its associated device will be physically separated and electrically isolated from one another. Thus, a large probe pad is electrically connected to an associated device only while the wafer is intact, facilitating probe placement during pre-bond testing. Once the devices are separated, the probe pad is disconnected from its associated active element portion, eliminating the capacitance associated with maintaining an electrical connection between a co-located probe and active region.

### BACKGROUND

Semiconductor devices are commonly tested in pre-bond form; that is, while still in the form of a wafer (or a piece/fragment thereof) and prior to being diced into separate components and bonded to a circuit subassembly. Pre-bond testing generally detects defects that are inherent in the manufacturing process (such as impurities or imperfections in the semiconductor regions). Each semiconductor device is formed to include a conductive area (probe pad) to be used for this testing. Pre-bond testing is performed using a device-by-device method, with an electronic probe brought into contact with the probe pad. The application of a specific test signal to the pad via the probe is used to determine if the device is operating properly. This pre-bond testing may be used to identify defective devices and eliminate them from the fabrication process before they become integrated with other (expensive) components.

### BRIEF DESCRIPTION OF THE DRAWINGS

FIG. 1 illustrates a common semiconductor wafer, showing location and placement of various semiconductor device regions on the wafer surface;

FIG. 2 shows a portion of a testing arrangement that may be used to perform pre-bond testing of a fabricated semiconductor wafer (or a piece/fragment thereof);

FIG. 3 is a view of a set of conventional semiconductor devices, as may be formed in the regions shown in FIG. 1;

FIG. 4 illustrates the same set of semiconductor devices as shown in FIG. 3, in this case subsequent to being diced into separate devices;

FIG. 5 illustrates a portion of a semiconductor wafer as formed in accordance with an embodiment of the present invention, with each probe pad location-shifted into an adjacent semiconductor device region;

FIG. 6 illustrates the devices of FIG. 5 subsequent to being separated into individual devices, particularly illustrating the break in the conductive path between the probe pad and active element portion of the semiconductor device that it tested;

FIG. 7 illustrates an alternative embodiment of the present invention;

FIG. 8 illustrates a subset of the devices shown in FIG. 7, in this case after the wafer has been diced to form the individual components and also showing the probe pads as coated with a material that facilitates bonding of the component to a larger subassembly;

FIG. 9 shows yet another configuration employing location-shifted probe pads, in this case formed as “twinned pairs” of semiconductor devices, with a probe pad on a first semiconductor device connected to an active region on a second semiconductor device, and vice versa;

FIG. 10 shows a pair of semiconductor devices of the configuration shown in FIG. 9, subsequent to being separated into individual components;

FIG. 11 illustrates an embodiment of the present invention in which the probe pad is location-shifted into an adjacent region that is devoid of any other elements (i.e., a “sacrificial” region);

FIG. 12 illustrates a single semiconductor device as separated from the semiconductor portion shown in FIG. 11; and

FIG. 13 shows another configuration utilizing location-shifted pre-bond probe pads, where in this arrangement a “twinned configuration” is formed to surround a vacant wafer area, with the test pads for a twinned pair disposed in the same vacant area.

### DETAILED DESCRIPTION

The wafers for implementation of testing configurations described in this application may be made of various solid-state materials suitable for semiconductor fabrication processes in the creation of electronic circuitry, optical circuitry, opto-electronic circuitry, or any of their variations. Examples of the materials suitable for use in the formation of these wafers include semiconductor materials (e.g., silicon or a III-V compound such as InP or GaAs), silicon-on-insulator (SOI) materials, glass materials and others.

Pre-bond testing of semiconductor devices may be performed on a semiconductor wafer as a whole (which may contain hundreds or thousands of similarly-formed semiconductor devices), or a portion of the wafer (such as a strip) that contains tens of these devices. Pre-bond testing and diagnosis can facilitate defect localization and/or repair prior to performing a bonding operation. The conductive probe pad formed in a region of each semiconductor device is electrically connected to an active element portion of the semiconductor device, such that the application of a test signal to the pad via a test probe will be able to determine if the active element is operating properly.

The larger the probe pad, within reason, the easier and more consistently the probe's needle tip may be placed on it and create a viable electrical contact. However, a large probe pad may be the source of performance problems later on during the use of the semiconductor device. In particular, the presence of a large conductive region (i.e., the probe pad) that is electrically coupled to the active element portion creates a parasitic capacitance. The capacitive load is particularly troublesome for high-speed applications, where the presence of an unwanted capacitance limits the operational speed of the active element.

FIG. 1 shows an example of a wafer 1 that is patterned to include a number of separate semiconductor device regions 2-1, 2-2, 2-3, and the like. At times, these “device regions” may be referred to as an individual semiconductor “component” or “die”. Each die may include one or more electronic and/or optical microstructures, designed to perform one or more specific functions or operations. Depending on the size of the wafer, hundreds or thousands of device regions 2 may be simultaneously formed.

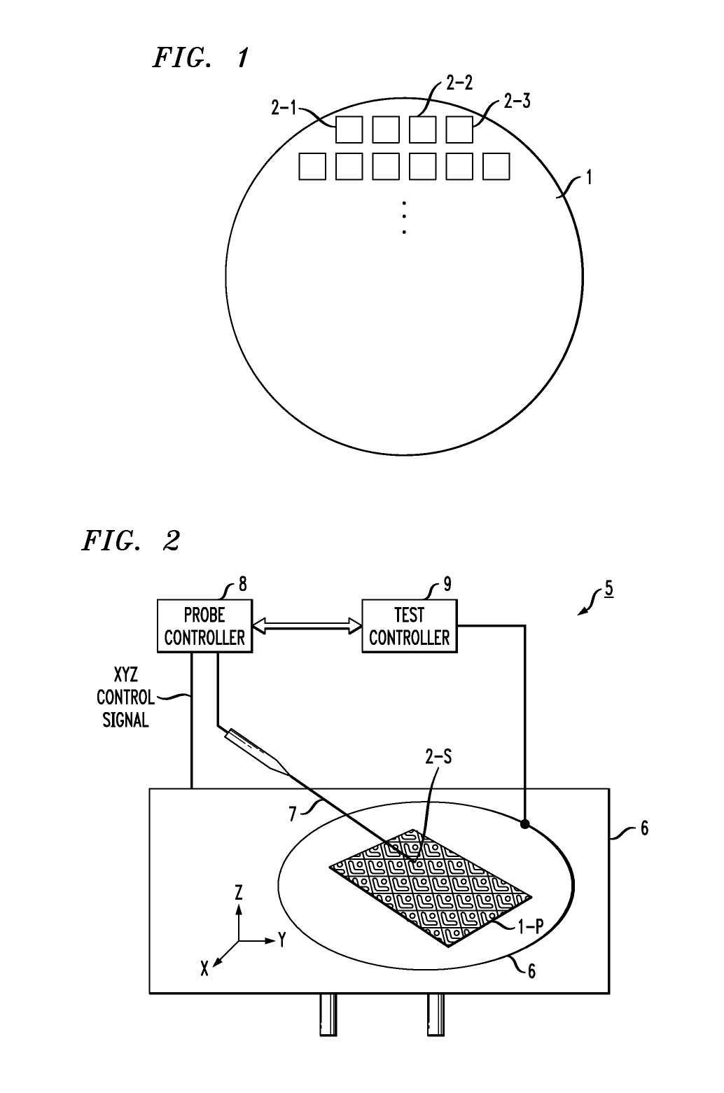

In order to minimize waste and control the costs of a finished semiconductor product, it is common to test each of the individual device elements 2 prior to incorporating the elements in a larger circuit arrangement (i.e., “pre-bond” testing). FIG. 2 is a diagram of a system 5 that may be used to perform this pre-bond testing (which may be referred to as “wafer-scale testing” at times, particularly when performed on the wafer as a whole; in general, any type of system that performs testing on multiple devices prior to integration in a larger assembly can be defined as a “multi-device” testing system, and is applicable to the purposes of the present invention). Depending on the particular test apparatus, type of device(s) and procedures, either a complete wafer may be pre-bond tested, or a portion of a wafer may be separated (sawn or cleaved) into a number of separate portions (each portion containing tens of device regions), with each separate portion individually tested.

In the arrangement shown in FIG. 2, a portion 1-P of wafer 1 is inserted in a pre-bond testing apparatus 6, with an electrical probe 7 used to contact a probe pad formed on a selected semiconductor device region 2-S. As described below, the probe pad is electrically connected to an active region of device 2-S, such that as a signal from probe controller 8 is applied to probe 7, the active device region is energized and its performance evaluated by test controller 9 of apparatus 6. If suitable for operation, the process continues with probe 7 moving along to test another semiconductor device 2 on wafer portion 1-P. If for some reason the tested device does not function properly, its identity is noted (by test controller 9, for example) so that it may be set aside and not used (at least without re-working) in forming a finished product.

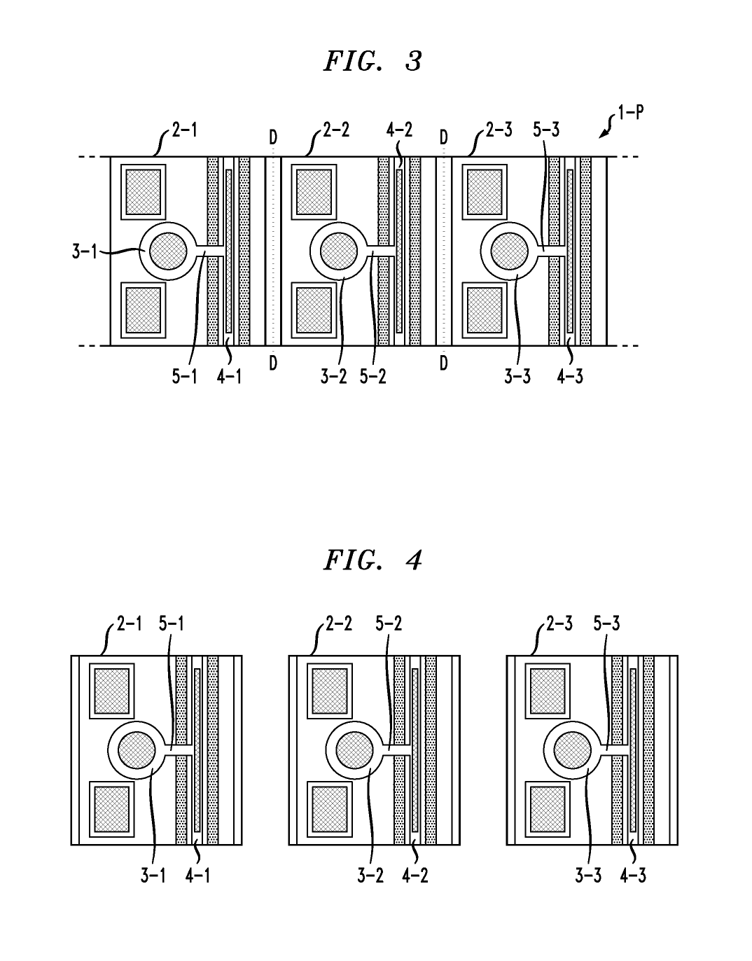

FIG. 3 illustrates a portion of a semiconductor wafer as commonly configured in the prior art to include a test pad area for providing a region for a test probe to contact the device and test its performance. In this case, FIG. 3 shows a set of three semiconductor devices 2-1, 2-2 and 2-3, in their pre-bonded form as a section (or “slice” or “bar”) of wafer 1. As shown, each semiconductor device includes a pre-bond probe pad 3-i electrically connected to an active element portion 4-i via a conductive lead 5-i (i=1, 2, 3). Pre-bond testing may be performed on the device configuration of FIG. 3 using apparatus 6 as shown in FIG. 2, bringing electrode 7 into contact with probe pad 3-1 (for example) and sending an electrical signal across conductive lead 5-1 to active element portion 4-1. If active element portion 4-1 does not function properly, that specific device 2-1 will be designated as “defective” by test controller 9. Otherwise, it will be understood that semiconductor device 2-1 performs satisfactorily and may be incorporated into a larger subsystem arrangement. As described above, the pre-bond testing continues by moving probe 7 to contact probe pad 3-2 of semiconductor device 2-2, testing the performance of active element portion 4-2, and so on, with each semiconductor device region 2-i being tested in turn.

As mentioned above, a large-sized probe pad (in terms of surface area) facilitates the ability to bring the needle point of the probe into contact with the probe pad quickly and reproducibly or repeatedly (in general, in a manner that requires minimal effort to align the needle point with the probe pad, is efficient and provides accurate results). However, once the wafer is separated into separate semiconductor devices (the separation ultimately performed along dotted lines D, as shown in FIG. 3), these probe pads remain electrically connected to the active element portion (via lead 5) and, as a result, may impact the performance of the active element, particularly at higher speeds. FIG. 4 illustrates the same set of semiconductor devices 2, in this case subsequent to being diced into separate components. As shown, each probe pad 3 remains electrically coupled to its associated active element portion 4 via conductive lead 5. As is typical in the industry, the surface area of probe pad 3 is relatively large with respect to the overall size of the die. This size leads to the possibility of creating a relatively large parasitic capacitance in the operation of the final device, which is particularly problematic for high speed applications.

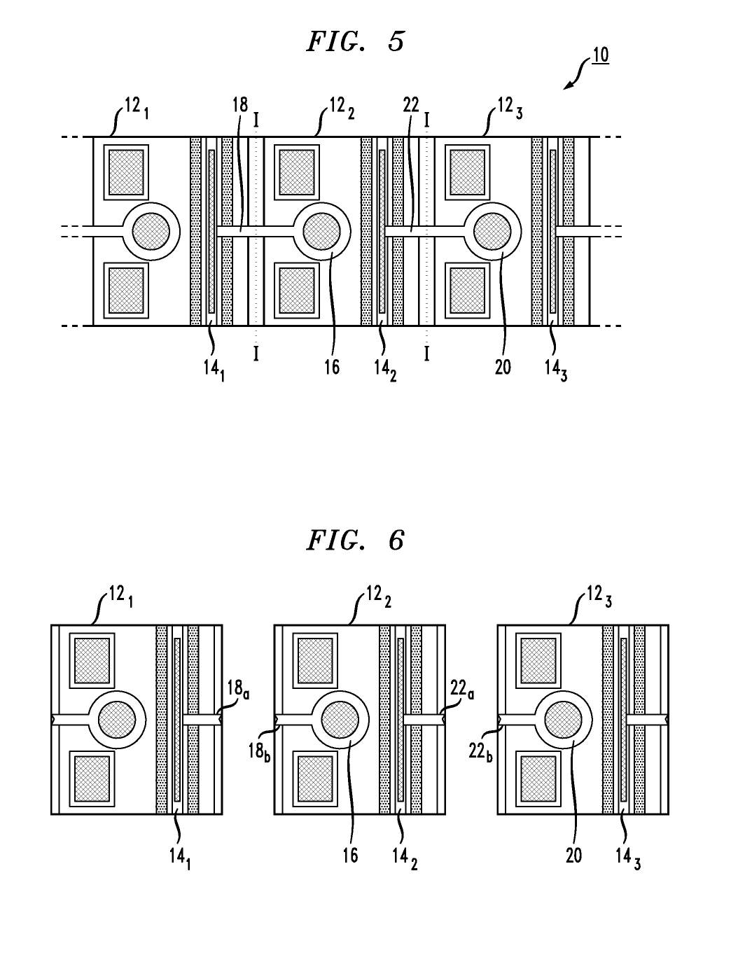

In contrast, FIG. 5 illustrates a portion of a semiconductor wafer as formed in accordance with an embodiment of the present invention, where the pre-bond probe pads are location-shifted such that the electrical connection between the probe pad and the active element portion of the semiconductor device is broken when the wafer is diced (or cleaved) into the separate semiconductor devices. In particular, the pre-bond probe pads are location-shifted into an adjacent semiconductor device site on the wafer, with the electrical connection crossing the interface between adjacent devices.

With reference to FIG. 5, a portion 10 of a semiconductor wafer is shown, illustrating semiconductor devices 12₁, 12₂ and 12₃. Each semiconductor device 12 includes an active element portion 14, shown as 14₁, 14₂ and 14₃ in FIG. 5. A pre-bond probe pad 16, which is used to energize and test active element 14₁ of semiconductor device 12₁, is shown as being location-shifted outside of the boundaries of device 12₁. In particular, pre-bond probe pad 16 is located within the boundaries of neighboring semiconductor device 12₂, with an electrical lead connector 18 crossing the interface between device 12₁ and device 12₂ to electrically connect active element 14₁ to pre-bond probe pad 16 (the interface indicated by the dotted line I-I). Thus, the pre-bond probe pad is location-shifted with respect to the active element that it is testing and, therefore, will be separated (both physically and electrically) from the active element upon dicing the wafer (or wafer portion) into individual elements.

As also shown in FIG. 5, the location-shifted testing arrangement further includes a pre-bond probe pad 20 that is positioned within the boundaries of semiconductor device 12₃, but is used to test active element 14₂ of semiconductor device 12₂. An electrical lead connector 22 is used to provide the electrical signal path between pre-bond probe pad 20 and active element portion 14₂.

The act of dicing/cleaving the wafer into separate semiconductor devices, therefore, causes the electrical connection between a pre-bond probe pad and its active element portion to be broken. FIG. 6 illustrates this configuration of the same set of semiconductor devices 12-1 through 12-3.

It is evident in the illustration of FIG. 6 that electrical lead 18 between probe pad 16 and active element portion 14₁ of semiconductor device 12₁ is broken during the process of sawing/cleaving apart the separate devices from the wafer structure, with a first section 18a shown as remaining connected to active element portion 14₁ (i.e., associated with semiconductor device 12₁) and a second section 18b shown as remaining connected to probe pad 16 (i.e., associated with semiconductor device 12₂). Electrical lead 22 is similarly severed during wafer dicing, separating pre-bond probe pad 20 from active element portion 14₂.

Looking specifically at semiconductor device 12₂, for example, it is clear that there is no electrical connection between active element 14₂ and probe pad 16, even though both features are included as part of semiconductor device 12₂, since active element 14₂ had been tested via location-shifted probe pad 20. With no electrical signal path between active element 14₂ and probe pad 16, the possibility of stray capacitance impacting the performance of semiconductor device 12-2 (associated with the presence of probe pad 16) is eliminated.

While shown for only a few devices, it is obvious that this configuration may be used across an entire wafer surface, location-shifting the pre-bond probe pads into adjacent device layouts, thus providing electrical isolation between the probe pads and the active device regions once pre-bond testing and chip separation are completed.

As a result, it is possible to utilize large-sized pre-bond probe pads (as preferred to facilitate the testing process) without compromising the high speed performance of the resultant device. Moreover, a large-sized probe pad may be coated with a larger volume of solder or epoxy, adding greater structural stability to the final semiconductor device (i.e., increasing the strength of the bond attachment by forming an additional or enlarged bond site on the device).

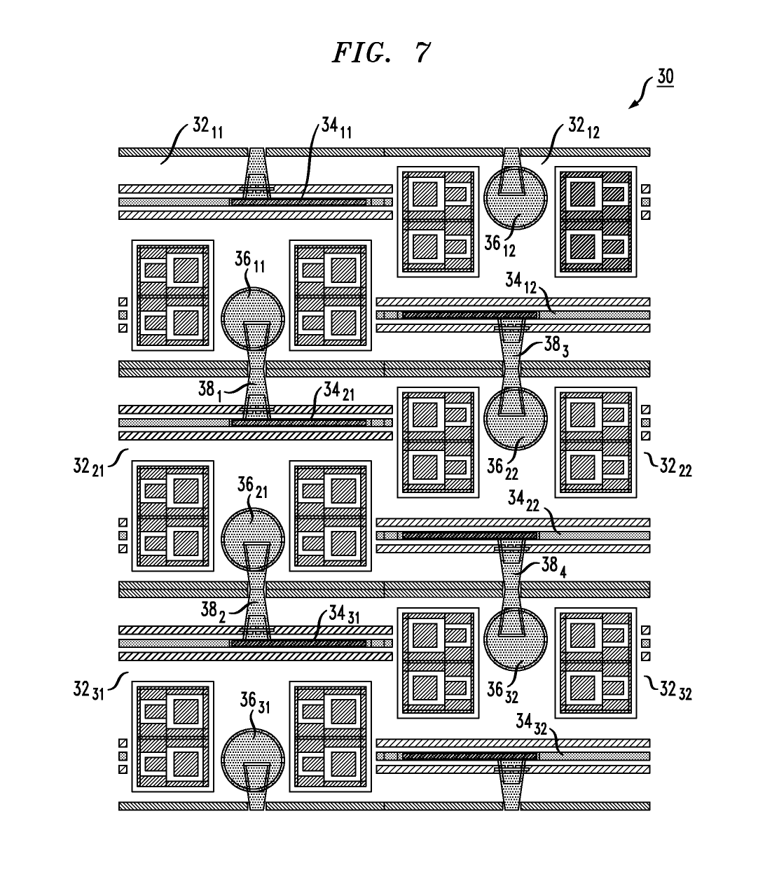

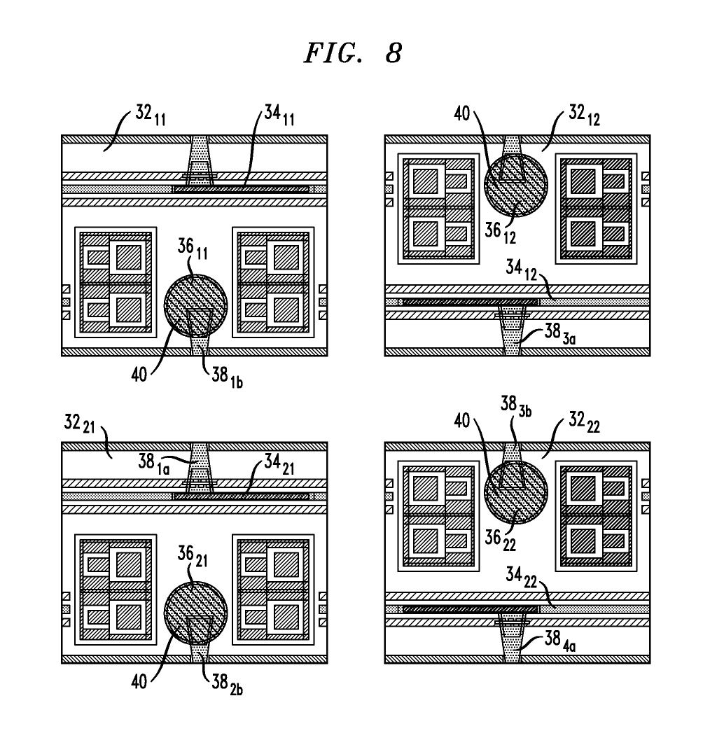

FIGS. 7 and 8 illustrate another example of providing location-shifted test pads for semiconductor devices. A portion 30 of a semiconductor wafer is shown, in this case including a set of six semiconductor devices 32₁₁-32₃₂. An active region 34_{xy} is included within each semiconductor device 32_{xy} (x=1, 2, 3; y=1, 2). A relatively large-sized probe pad 36_{xy} is also formed in each semiconductor device 32_{xy}. Again, there is no electrical connection created between the active region 34_{xy} and probe pad 36_{xy} formed within the boundaries of the same semiconductor device 32_{xy}. Referring in particular to semiconductor device 32₃₁ (for example), it is shown that active region 34₃₁ of device 32₃₁ is tested via probe pad 36₂₁ formed within device 32₂₁, with a conductive lead 38₂ providing the electrical connection between these two elements which are still in wafer form. In similar fashion, electrical connection 38₁ is shown as providing the electrical connection between probe pad 36₁₁ and active region 34₂₁, electrical connection 38₃ is shown as providing the electrical connection between probe pad 36₂₂ and active region 34₁₂, and electrical connection 38₄ provides the connection between probe pad 36₃₂ and active region 34₂₂.

It is possible to take advantage of the relatively large size of probe pads 36_{xy}, for example to improve the mechanical stability of the subsequently-formed system. In particular, probe pads 36_{xy} may be coated with an epoxy material 40 (subsequent to the testing operation) which will add mechanical strength to the bonded assembly. The illustration of this embodiment as shown in FIG. 8 includes the addition of epoxy material 40 on each pad 36_{xy}. It is to be understood that a solder material may be used in place of an epoxy to add structural support to the individual component.

Once the pre-bond testing is completed and the defective semiconductor devices are identified, the structure as shown in FIG. 7 is separated to form individual devices (die), using any well-known technique. Four of the individual devices 32₁₁, 32₂₁, 32₁₂ and 32₂₂ are shown in FIG. 8. Again, the severing of conductive leads 38ₓ as used for pre-bond testing eliminates the signal path between each location-shifted probe pad and its associated active region. The use of location-shifted probe pads ensures that there is no electrical connection between the active region and the probe pad that is included within the boundaries of the same semiconductor device. See, for example, semiconductor device 32₁₁ which includes active element 34₁₁ and probe pad 36₁₁. No conductive path is formed between these features; probe pad 36₁₁ had been used to test active region 34₂₁ of device 32₂₁ (i.e., probe pad 36₁₁ is location-shifted out of the boundary area of semiconductor device 32₂₁).

After the devices are separated as shown in FIG. 8, and immediately prior to (or during) a bonding operation where an individual device is attached to a larger assembly, an epoxy coating 40 can be attached to probe pads 36_{xy}. As mentioned above, the addition of epoxy material 40 may improve the mechanical stability of the semiconductor device in the final assembly structure.

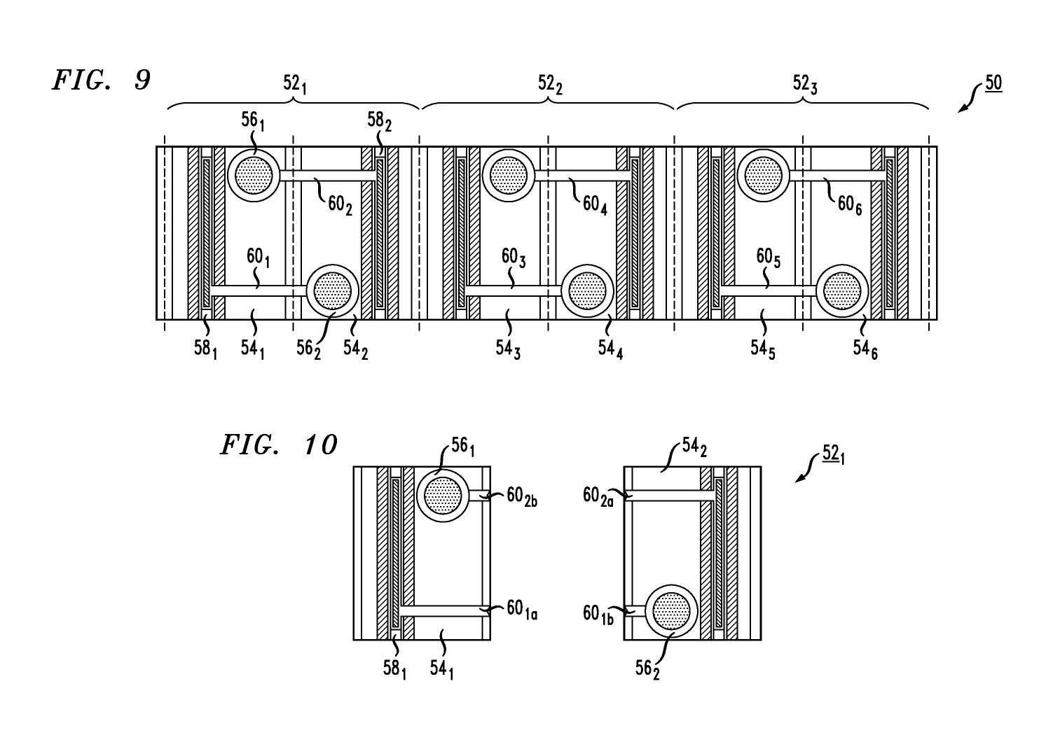

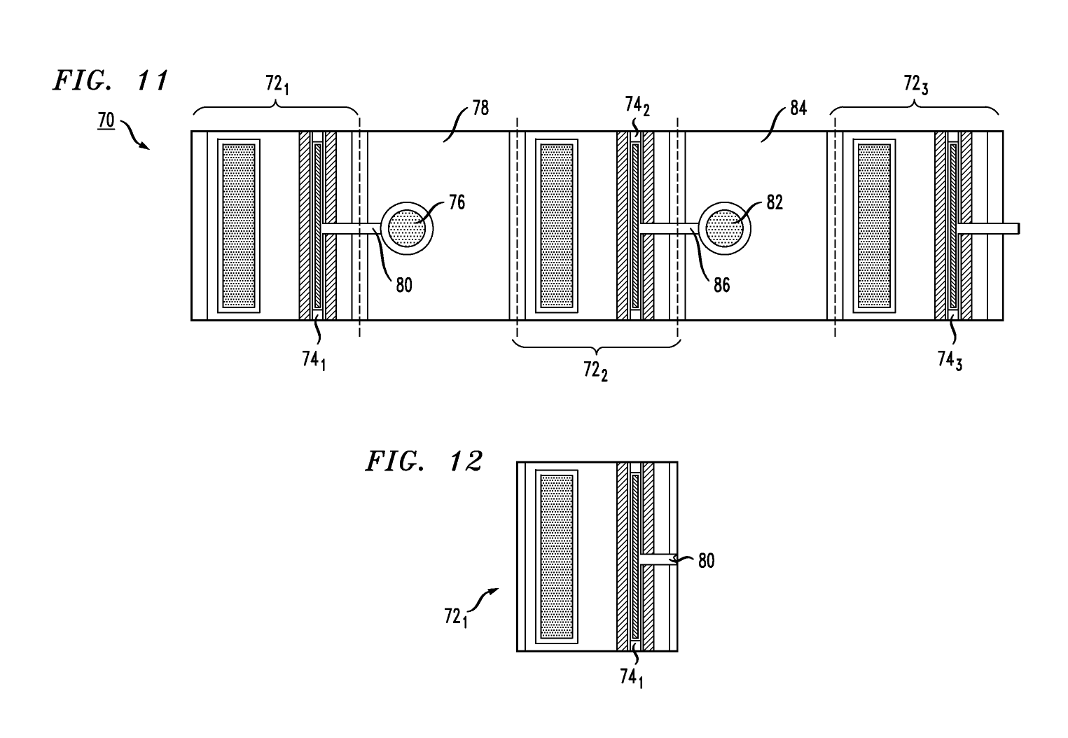

While the embodiments shown above are useful in understanding the concept of employing location-shifted probe pads, there are a variety of other configurations which are considered to utilize these same principles. For example, FIGS. 9 and 10 illustrate another configuration, where in this case a semiconductor wafer (or portion of a wafer) is formed to include “twinned pairs” of semiconductor devices, with a probe pad on a first semiconductor device connected to an active region on a second semiconductor device, and vice versa.

In particular, FIG. 9 illustrates a portion 50 of a semiconductor wafer, where portion 50 includes a set of three pairs of semiconductor devices, shown as pairs 52₁, 52₂ and 52₃. Each pair 52₁ is shown as including two individual semiconductor devices disposed in an anti-symmetric relationship, with pair 52₁ including semiconductor devices 54₁ and 54₂, pair 52₂ including semiconductor devices 54₃ and 54₄, and pair 52₃ including semiconductor devices 54₅ and 54₆. Referring in particular to semiconductor device 54₁, it is shown as including a probe pad 56₁ and an active region 58₁. Semiconductor device 54₂ includes similar elements, but oriented 180° with respect to the components in device 54₁ (i.e., in an “anti-symmetric” relationship, also referred to as a “twinned pair”, as noted above).

In accordance with this particular example, a pair of separate electrical conductors is coupled between the devices forming a specific anti-symmetric pair. As shown in particular for pair 52₁, a first conductive lead 60₁ is used as the electrical connection between active region 58₁ of semiconductor device 54₁ and probe pad 56₂ of semiconductor device 54₂. A second conductive lead 60₂ is shown as providing the electrical connection between probe pad 56₁ of semiconductor device 54₁ and active region 58₂ of semiconductor device 54₂. A pair of conductive leads 60₃, 60₄ is shown as interconnecting probe pads and active regions within second pair 52₂. Third pair 52₃ includes conductive leads 60₅ and 60₆, which are used in the same manner.

As with the different embodiments described above, there is no electrical connection between the active region 58ᵢ and probe pad 56ᵢ of any individual semiconductor device 54ᵢ. That is, the probe pad utilized to provide testing of an active region of a specific semiconductor device has been “location-shifted” to be outside the borders of that specific device.

FIG. 10 illustrates devices 54₁ and 54₂ of FIG. 9, subsequent to being severed into separate, individual components. It is clearly shown that conductive leads 60₁ and 60₂ are also severed in this process, breaking the electrical connection between the two semiconductor devices. In the specific illustration of FIG. 10, semiconductor device 54₁ is shown as including severed portions 60₁ₐ and 60_{2b} of conductive leads 60₁ and 60₂, respectively. Device 54₂ is shown as including severed portions 60_{1b} and 60₂ₐ of the original conductive leads 60₁ and 60₂. Without any electrical connection between the remaining portions of the conductive leads 60_{ib} and the active region 58ᵢ of each device, the ultimate performance (particularly high speed performance) of the semiconductor devices will not be affected by stray capacitance associated with the probe pad remaining on the final device structure.

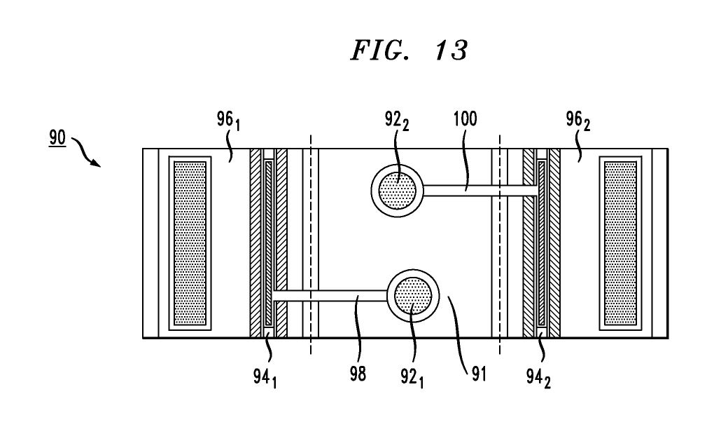

FIGS. 11 and 12 illustrate another possible configuration for utilizing location-shifted probe pads. In this case, the probe pad is location-shifted into an adjacent region of the wafer that is devoid of any other elements (i.e., a “sacrificial” or “vacant” region). Referring to FIG. 11, a wafer portion 70 is shown as including a set of three semiconductor devices, denoted 72₁, 72₂ and 72₃. In this case, each semiconductor device 72ᵢ is shown as including an associated active region 74ᵢ. In order to perform pre-bond testing, a probe pad 76 is location-shifted outside of the boundary of semiconductor device 72₁ and is instead formed in a vacant wafer area 78 adjacent to semiconductor device 72₁. A conductive lead 80 is used to provide the electrical connection between probe pad 76 and active region 74₁, extending from vacant area 78 into semiconductor device 72₁. Similarly, a probe pad 82 is shown as being location-shifted with respect to semiconductor device 72₂ and instead formed in a vacant wafer area 84 adjacent to semiconductor device 72₂. A conductive lead 86 is used to form the electrical connection between active region 74₂ and probe pad 82.

Upon dicing wafer portion 70 into separate devices (along the dotted lines shown in FIG. 11), vacant wafer areas 78 and 84 (and the remaining similar areas) are disposed of as waste material. Semiconductor device 72₁ is shown in FIG. 12 in its individual form, where only a small portion of conductive lead 80 remains. No probe pad remains in this final semiconductor device structure, thus decreasing the overall size of the semiconductor device (a desirable feature in many applications).

It is to be understood that the size of the “vacant wafer areas” within which the probe pads are formed can be minimized so as to reduce the amount of waste material that is created. Indeed, it is possible to combine the anti-symmetric configuration of FIG. 9 with the “vacant area” configuration of FIG. 11, resulting in an arrangement 90 as shown in FIG. 13, where vacant area 91 includes a pair of probe pads 92₁ and 92₂ used to test (respectively) a pair of active regions 94₁ and 94₂ formed in semiconductor devices 96₁ and 96₂, respectively. In this arrangement as shown in FIG. 13, semiconductor devices 96₁ and 96₂ are located on either side of vacant area 91. Also shown is a conductive lead 98 that is used to provide the electrical connection between probe pad 92₁ and active region 94₁, and a conductive lead 100 that is used to provide the electrical connection between probe pad 92₂ and active region 94₂. As with the configuration described above in association with FIGS. 9 and 10, once devices 96₁ and 96₂ are sawn from the wafer portion, they will not be susceptible to probe pad-related parasitic capacitance, since the probe pads were located in a ‘vacant area’ of the wafer portion and disposed of as waste material.

It will be further understood that various changes in the details, materials, and arrangements of the parts which have been described and illustrated in order to explain the nature of this invention may be made by those skilled in the art without departing from the scope of the invention as expressed in the following claims.

What is claimed is:

1. A semiconductor device comprising
an active element portion;
a pre-bond probe pad disposed on the semiconductor device and electrically isolated from the active element portion; and
a first conductive lead coupled to the pre-bond probe pad and extending outward toward a boundary of the semiconductor device; and
a second, separate conductive lead coupled to the active element portion and extending outward toward a boundary of the semiconductor device.

2. A semiconductor device as defined in claim 1 wherein the first and second conductive leads extend in opposite directions toward opposite outer boundaries of the semiconductor device.

3. A semiconductor device as defined in claim 1 wherein the first and second conductive leads extend in a same direction toward a common boundary of the semiconductor device.

4. A semiconductor device as defined in claim 3 wherein the first and second conductive leads extend toward a second semiconductor device disposed in an anti-symmetric relationship thereto.

5. A semiconductor device as defined in claim 1 wherein the pre-bond probe pad is coated with an epoxy material subsequent to pre-bond testing.

6. A semiconductor device as defined in claim 1 wherein the pre-bond probe pad is coated with an amount of solder sufficient to provide structural support to the semiconductor device in a bonded assembly.

7. A semiconductor device as defined in claim 1 wherein the device is an electronic device.

8. A semiconductor device as defined in claim 1 wherein the device is an opto-electronic device.

9. A semiconductor device as defined in claim 1 wherein the device is an optical device.

10. A pre-bond testing configuration of at least a portion of a semiconductor wafer comprising
a plurality of semiconductor devices, each including an active region to be tested;
a plurality of test pads associated with the plurality of semiconductor devices in a one-to-one relationship, each test pad location-shifted within the pre-bond testing configuration to be disposed beyond the boundaries of its associated semiconductor device; and
a plurality of test signal conductors, each test signal conductor coupled between a location-shifted test pad and its associated active region, wherein subsequent to testing, the portion of the semiconductor wafer is separated into individual semiconductor devices such that each test signal conductor is broken.

11. A pre-bond testing configuration as defined in claim 10 wherein each test pad is location shifted into an adjacent semiconductor device region on the portion of the semiconductor wafer.

12. A pre-bond testing configuration as defined in claim 11 wherein pairs of semiconductor device regions are formed in an anti-symmetric configuration such that a first test signal conductor from a first semiconductor device is coupled between a test pad on the first semiconductor device and an active region on a second semiconductor device, and a second test signal conductor from the second semiconductor device is coupled between a test pad on the second semiconductor device and an active region on the first semiconductor device.

13. A pre-bond testing configuration as defined in claim 12 wherein for each individual device, the test pad located within the boundaries of the individual device is electrically isolated from the active region located therein.

14. A pre-bond testing configuration as defined in claim 10 wherein each test pad is location-shifted into a vacant area of the portion of the semiconductor wafer.

15. A semiconductor wafer including location-shifted probe pads, the wafer comprising
a plurality of semiconductor devices formed in defined regions across a surface of the semiconductor wafer, each semiconductor device including at least one active element to be tested in a multi-device system, the semiconductor wafer formed such that a probe pad for testing an active element in a first semiconductor device formed in a first region is location-shifted to be disposed outside of the first region into a second region on the semiconductor wafer, and further including a plurality of electrical leads coupled between the probe pads and the active elements of the plurality of semiconductor devices.

16. A semiconductor wafer as defined in claim 15 wherein a probe pad for testing an active element of a first semiconductor device is disposed within a second semiconductor device region, with an electrical lead between the probe pad and the active element crossing an interface between the first semiconductor device region and the second semiconductor device region.

17. A semiconductor wafer as defined in claim 15 wherein a probe pad for testing an active element of a first semiconductor device is disposed within a vacant region on the semiconductor wafer, with an electrical lead between the probe pad and the active element crossing an interface between the first semiconductor device region and the vacant region.

18. A semiconductor wafer as defined in claim 15 wherein pairs of semiconductor device regions are formed in an anti-symmetric configuration such that a first test signal conductor from a first semiconductor device is coupled between a test pad on the first semiconductor device and an active region on a second semiconductor device, and a second test signal conductor from the second semiconductor device is coupled between a test pad on the second semiconductor device and an active region on the first semiconductor device.

19. A semiconductor wafer as defined in claim 15 wherein pairs of semiconductor device regions are formed in an anti-symmetric configuration with a vacant region disposed therebetween such that a first test signal conductor from an active region of a first semiconductor device of a pair of semiconductor device regions is coupled to a first test pad in the vacant region, and a second test signal conductor from an active region of the second semiconductor device of the pair of semiconductor device regions is coupled to a second test pad in the vacant region.

20. A semiconductor wafer as defined in claim 15 wherein the semiconductor wafer comprises a silicon wafer.
